(19) United States
(12) Patent Application Publication
(10) Pub. No.: US 2025/0204165 A1
(43) Pub. Date: Jun. 19, 2025

(54) DISPLAY APPARATUS HAVING LIGHT-EMITTING DEVICES AND SEPARATING TRENCHES

(71) Applicant: LG Display Co., Ltd., Seoul (KR)

(72) Inventors: Seung Min BAIK, Paju-si (KR); Se In SON, Paju-si (KR); Ki Suk KANG, Paju-si (KR)

(73) Assignee: LG Display Co., Ltd., Seoul (KR)

(21) Appl. No.: 18/945,036

(22) Filed: Nov. 12, 2024

(30) Foreign Application Priority Data
Dec. 18, 2023 (KR) 10-2023-0184576

(51) Int. Cl. H10K 59/122

(52) U.S. Cl. CPC H10K 59/122

(57) ABSTRACT

A display apparatus includes light-emitting devices and separation trenches. The light-emitting devices can be disposed on emission areas defined by the separation trenches. Each of the light-emitting devices can include a charge generation layer disposed between a first emission stack and a second emission stack. The separation trenches can include first trenches extending in a first direction and second trenches extending in a second direction perpendicular to the first direction. The second trenches can be spaced apart from the first trenches. Separation structures can be disposed between the first trenches and the second trenches. Each of the separation structures can have an under-cut structure. Thus, in the display apparatus, the current leakage through the charge generation layer can be prevented. And, in the display apparatus, the defects due to the electric connection between a second electrode of each light-emitting device and the charge generation layer can be prevented.

### CROSS-REFERENCE TO RELATED APPLICATIONS

This application claims the benefit of Korean Patent Application No. 10-2023-0184576, filed on Dec. 18, 2023, which is hereby incorporated by reference as if fully set forth herein.

### BACKGROUND

### Technical Field of the Invention

The present disclosure relates to a display apparatus that light-emitting devices are disposed on emission areas defined by separating trenches.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit disposed between a first electrode and a second electrode. The light-emitting unit can include a plurality of emission material layers. For example, the light-emitting unit can include a charge generation layer disposed between a first emission stack and a second emission stack.

The light-emitting devices can be disposed on emission areas. The emission areas can be defined by separating trenches. For example, the separating trenches can include first trenches extending in a first direction and a second trenches extending in a second direction perpendicular to the first direction. Each of the emission areas can be surrounded by the first trenches and the second trenches. For example, the charge generation layer of each light-emitting device can be separated from the charge generation layer of adjacent light-emitting device by the first trenches and the second trenches.

The separating trenches can be formed in a planarization layer. For example, the light-emitting device of each emission area can be disposed on the planarization layer. Each of the second trenches can intersect the first trenches. Thus, in the display apparatus, a groove having a relative wide width can be formed in a portion of the planarization layer that is disposed between the emission areas adjacent in a diagonal direction inclined to the first direction and the second direction by the first trenches and the second trenches. Therefore, in the display apparatus, the second electrode of each emission area can be in contact with the charge generation layer of the corresponding emission area inside the groove having a relative wide width formed in a portion of the planarization layer that is disposed between the emission areas adjacent in the diagonal direction. That is, in the display apparatus, the light-emitting device on each emission area can't be normally operated due to the electric connection between the charge generation layer and the second electrode in the corresponding emission area.

### SUMMARY

Accordingly, embodiments of the present disclosure are directed to a display apparatus having light-emitting devices and separating trenches that substantially obviates one or more problems due to limitations and disadvantages of the related art.

An aspect of the present disclosure is to provide a display apparatus capable of preventing the leakage current through the charge generation layer.

Another aspect of the present disclosure is to provide a display apparatus capable of preventing the electric connection between the charge generation layer and the second electrode on each emission area.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve and other aspects of the inventive concepts, as embodied and broadly described herein, a display apparatus comprises a device substrate. Separation structures are disposed on the device substrate. The separation structures are disposed side by side in a first direction and a second direction. The second direction is perpendicular to the first direction. First trenches are disposed between the separation structures adjacent in the first direction. Each of the first trenches extends in the first direction. Second trenches are disposed between the separation structures adjacent in the second direction. Each of the second tranches extends in the second direction. The first trenches and the second trenches define emission areas. Light-emitting devices are disposed on the emission areas. Each of the light-emitting devices includes a charge generation layer disposed between a first emission stack and a second emission stack. Each of the separation structures includes a separating support and a separating cap. The separating cap is disposed on the separating support. A lower surface of the separating cap toward the device substrate has a greater that a width of the separating support.

The separating support and the separating cap can include an insulating material.

A distance between the device substrate and the lower surface of the separating cap can be larger than a distance between the device substrate and the charge generation layer.

A width of each second trench can be the same as a width of each first trench.

A first electrode of each light-emitting structure can be partially exposed by fences. The separating support of each separation structure can be disposed between the fences.

The separating support of each separation structure can include a different material from the fences.

In another aspect, a display apparatus comprises a first light-emitting device disposed on a first emission area. The first light-emitting device includes a first charge generation layer. A second light-emitting device is disposed on a second emission area adjacent to the first emission area in a first direction. The second light-emitting device includes a second charge generation layer. A third light-emitting device is disposed on a third emission area adjacent to the first emission area in a second direction. The second direction is perpendicular to the first direction. The third light-emitting device includes a third charge generation layer. A first trench is disposed between the first emission area and the second emission area. The first trench extends the second direction. A second trench is disposed between the first emission area and the second emission area. The second trench extends in the first direction. A separation structure is disposed between the second emission area and the third emission area. The separation structure has an under-cut structure. The first charge generation layer, the second charge generation layer and the third charge generation layer are spaced apart from each other. The first trench and the second trench are spaced apart from the separation structure.

A spaced area between the first charge generation layer and the second charge generation layer can overlap the first trench. A spaced area between the first charge generation layer and the third charge generation layer can overlap the second trench. And, a spaced area between the second charge generation layer and the third charge generation layer can overlap the separation structure.

The separation structure can include a separating support and a separating cap. The separating cap can be disposed on the separating support. The maximum width of the separating cap in the first direction can be larger than a width of the first trench. The maximum width of the separating cap in the second direction can be larger than a width of the second trench.

The maximum width of the separating cap in the first direction can be smaller than a distance between the first emission area and the second emission area. The maximum width of the separating cap in the second direction can be smaller than a distance between the first emission area and the third emission area.

A distance between the first emission area and the first trench can be different from a distance between the first trench and the second emission area. A distance between the first emission area and the second trench can be different from a distance between the second trench and the third emission area.

The distance between the first emission area and the first trench can be the same as the distance between the second trench and the third emission area. The distance between the first emission area and the second trench can be the same as the distance between the first emission area and the second trench.

The separation structure can include a first support, a second support and a separating cap. The first support can be disposed side by side with the first trench in the second direction. The second support can be disposed side by side with the second trench in the first direction. The separating cap can be disposed on the first support and the second support.

A third trench can be disposed between the first emission area and the separation structure. The third trench can extend in a direction inclined to the first direction and the second direction. The third trench can be spaced apart from the first trench and the second trench.

A width of the third trench can be the same as a width of the first trench and a width of the second trench.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K region in FIG. 1;

FIG. 4 is a view taken along I-I′ of FIG. 3;

FIG. 5 is a view taken along II-II′ of FIG. 3;

FIG. 6 is a view taken along III-III′ of FIG. 3; and

FIGS. 7 to 14 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

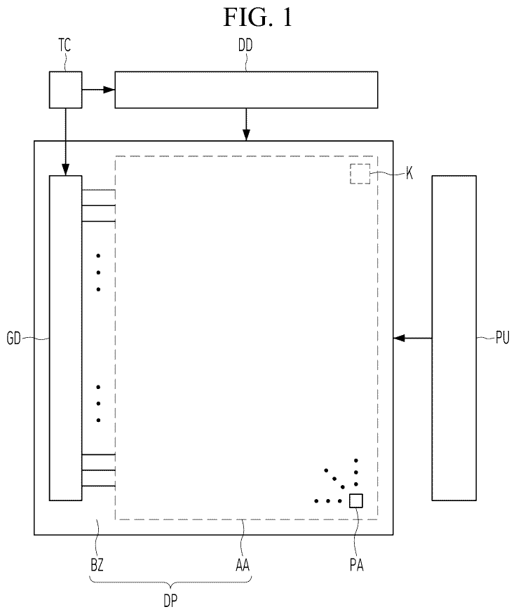

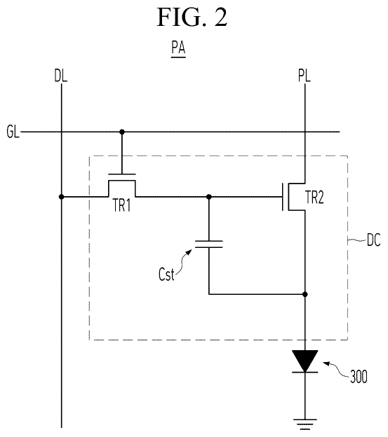

FIG. 1 is a view schematically showing a display apparatus according to an embodiment of the present disclosure. FIG. 2 is a view showing a circuit of a pixel area in the display apparatus according to the embodiment of the present disclosure.

Referring to FIGS. 1 and 2, the display apparatus according to the embodiment of the present disclosure can include a display panel DP. The display panel DP can generate an image provided to a user. For example, a plurality of pixel areas PA can be disposed within the display panel DP. Various signals can be provided in each pixel area PA through signal wirings GL, DL and PL. For example, the signal wirings GL, DL and PL can include gate lines GL sequentially applying a gate signal, data lines DL applying a data signal, and power voltage supply lines PL supplying a power voltage.

The gate lines GL can be electrically connected to a gate driver GD. The data lines DL can be electrically connected to a data driver DD. The power voltage supply lines PL can be electrically connected to a power unit PU. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC.

The display panel DP can include the active area AA in which the pixel areas PA are disposed, and a bezel area BZ disposed outside the active area AA. The pixel areas PA do not overlap the bezel area BZ. For example, the active area AA can be surrounded by the bezel area BZ. The gate driver GD, the data driver DD, the power unit PU and the timing controller TC can be disposed outside the active area AA. For example, each of the signal wirings GL, DL and PL can include a region disposed on the bezel area BZ.

At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color according to a signal applied through the signal wirings GL, DL and PL. For example, a driving circuit DC electrically connected to a light-emitting device 300 can be disposed in each pixel area PA. The driving circuit DC of each pixel area PA can be electrically connected to the signal wirings GL, DL and PL. For example, the driving circuit DC of each pixel area PA can be connected to one of the gate lines GL, one of the data lines DL and one of the power voltage supply lines PL. The driving circuit DC of each pixel area PA can supply a driving current corresponding to the data signal to the light-emitting device 300 of the corresponding pixel area PA according to the gate signal for one frame. For example, the driving circuit DC of each pixel area PA can include a first thin film transistor TR1, a second thin film transistor TR2 and a storage capacitor Cst.

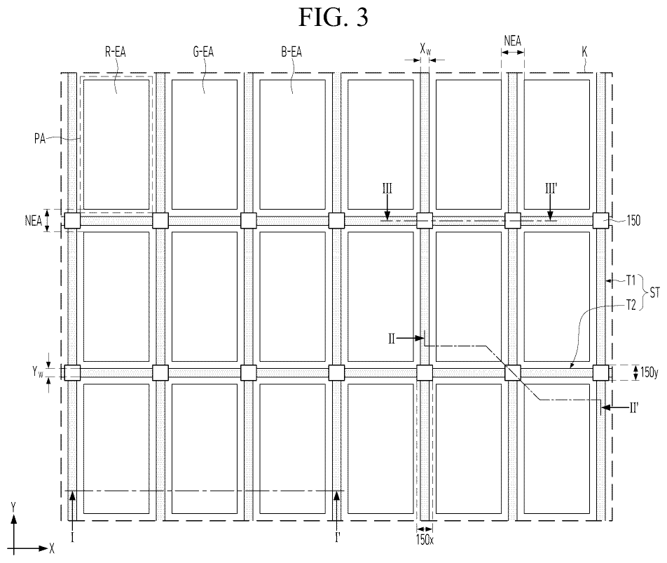

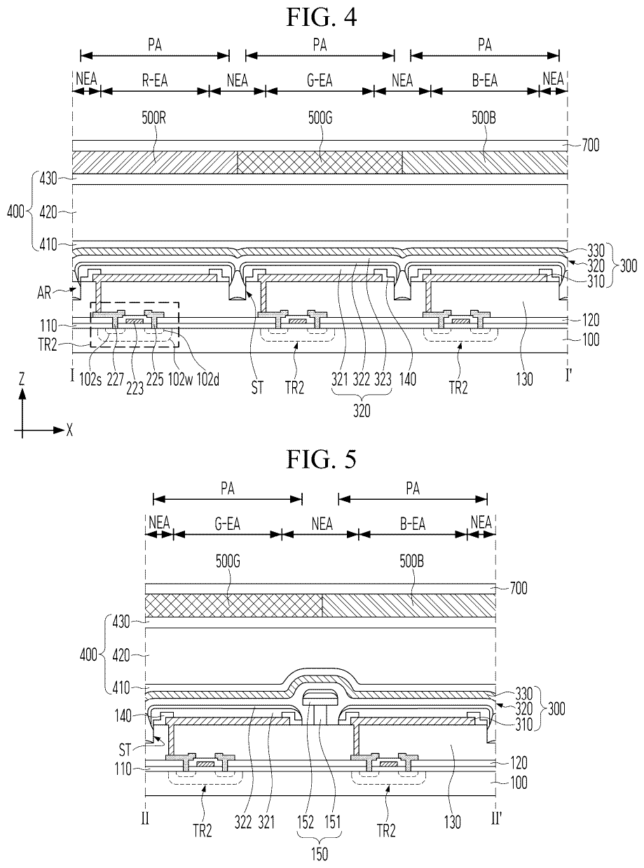

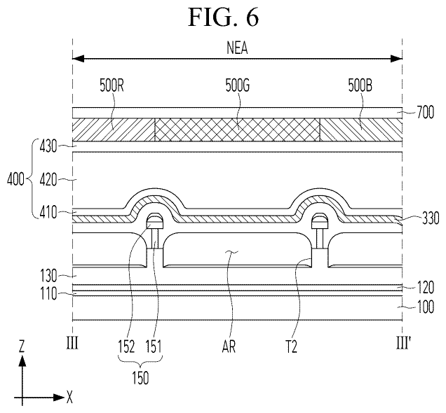

FIG. 3 is an enlarged view of K region in FIG. 1. FIG. 4 is a view taken along I-I′ of FIG. 3. FIG. 5 is a view taken along II-II′ of FIG. 3. FIG. 6 is a view taken along III-III′ of FIG. 3.

Referring to FIGS. 2 to 6, in the display apparatus according to the embodiment of the present disclosure, the driving circuit DC and the light-emitting device 300 of each pixel area PA can be supported by a device substrate 100. The device substrate 100 can include various materials. For example, the device substrate 100 can be a wafer made of a semiconductor material, such as silicon. At least one of the driving circuit DC in each pixel area PA can be formed within the device substrate 100. Thus, in the display apparatus according to the embodiment of the present disclosure, the density of the pixel circuit DC in each pixel area PA can be improved.

The first thin film transistor TR1 of each pixel area PA can transmit the data signal to the second thin film transistor TR2 of the corresponding pixel area PA according to the gate signal. For example, the first thin film transistor TR1 of each pixel area PA can be a switching thin film transistor. The first thin film transistor TR1 of each pixel area PA can include a first well region, a first drain region, a first source region, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The first well region, the first drain region and the first source region can be formed within the device substrate 100. For example, the first well region, the first drain region and the first source region can be formed by a process of doping the device substrate 100 with conductive impurities. The first drain region and the first source region can include different conductive impurities from the first well region. For example, the first well region can include P-type impurities, and the first drain region and the first source region can include N-type impurities. The first drain region and the first source region can be formed in the first well region. For example, a portion of the first well region disposed between the first drain region and the first source region can function as a first channel region of the first thin film transistor TR1.

The first gate electrode can be disposed on the device substrate 100. The first gate electrode can be disposed between the first drain region and the first source region. For example, the first gate electrode can overlap the portion of the first well region, which functions as the first channel region. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the device substrate 100. The first gate electrode can be insulated from the device substrate 100. For example, the first drain region can be electrically connected to the first source region according to a voltage applied to the first gate electrode.

The first drain electrode can be disposed on the device substrate 100. The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region. The first drain electrode can be insulated from the first gate electrode.

The first source electrode can be disposed on the device substrate 100. The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. For example, the first source electrode can be disposed on a different layer from the first gate electrode. The first source electrode can be disposed on a same layer as the first drain electrode. For example, the first source electrode can include a same material as the first drain electrode. The first source electrode can be formed by a same process as the first drain electrode. For example, the first source electrode can be formed simultaneously with the first drain electrode. The first source electrode can be electrically connected to the first source region. The first source electrode can be insulated from the first gate electrode. The first source electrode can be spaced apart from the first drain electrode.

The second thin film transistor TR2 of each pixel area PA can generate the driving current corresponding to the data signal. For example, the second thin film transistor TR2 of each pixel area PA can be a driving thin film transistor. The second thin film transistor TR2 of pixel area PA can include a second well region 102w, a second drain region 102d, a second source region 102s, a second gate electrode 223, a second drain electrode 225 and a second source electrode 227. For example, the second gate electrode 223 of each pixel area PA can be electrically connected to the first source electrode of the corresponding pixel area PA, and the second drain electrode 225 of each pixel area PA can be electrically connected to the corresponding power voltage supply line PL.

The second well region 102w, the second drain region 102d and the second source region 102s can be formed within the device substrate 100. For example, the second well region 102w, the second drain region 102d and the second source region 102s can be formed by a process of doping the device substrate 100 with conductive impurities. The second drain region 102d and the second source region 102s can include different conductive impurities from the second well region 102w. For example, the second well region 102w can include N-type impurities, and the second drain region 102d and the second source region 102s can include P-type impurities. Thus, in the display apparatus according to the embodiment of the present disclosure, the second thin film transistor TR2 of each pixel area PA can have electrical characteristics different from the first thin film transistor TR1 of the corresponding pixel area PA.

The second well region 102w can include conductive impurities same as the first drain region and the first source region. The second well region 102w can be formed by a same process as the first drain region and the first source region. For example, the second well region 102w can be formed simultaneously with the first drain region and the first source region. The second drain region 102d and the second source region 102s can include conductive impurities same as the first well region. The second drain region 102d and the second source region 102s can be formed by a same process of the first well region. For example, the second drain region 102d and the second source region 102s can be formed simultaneously with the first well region. Thus, in the display apparatus according to the embodiment of the present disclosure, a process of forming the first thin film transistor TR1 and the second thin film transistor TR2 having electrical characteristics different from the first thin film transistor TR1 in each pixel area PA can be simplified.

The second drain region 102d and the second source region 102s can be formed within the second well region 102w. For example, a portion of the second well region 102w disposed between the second drain region 102d and the second source region 102s can function as a second channel region of the second thin film transistor TR2.

The second gate electrode 223 can be disposed on the device substrate 100. The second gate electrode 223 can be disposed between the second drain region 102d and the second source region 102s. For example, the second gate electrode 223 can overlap the portion of the second well region 102w which functions as the second channel region. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the device substrate 100. The second gate electrode 223 can be insulated from the device substrate 100. For example, the portion of the second well region 102w functioning as the second channel region can have an electrical conductivity corresponding to a voltage applied to the second gate electrode 223.

The second gate electrode 223 can be disposed on a same layer as the first gate electrode. The second gate electrode 223 can include a same material as the first gate electrode. The second gate electrode 223 can be formed by a same process as the first gate electrode. For example, the second gate electrode 223 can be formed simultaneously with the first gate electrode.

The second drain electrode 225 can be disposed on the device substrate 100. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region 102d. The second drain electrode 225 can be insulated from the second gate electrode 223.

The second drain electrode 225 can be disposed on a same layer as the first drain electrode. The second drain electrode 225 can include a same material as the first drain electrode. The second drain electrode 225 can be formed by a same process as the first drain electrode. For example, the second drain electrode 225 can be formed simultaneously with the first drain electrode.

The second source electrode 227 can be disposed on the device substrate 100. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. For example, the second source electrode 227 can be disposed on a different layer from the second gate electrode 223. The second source electrode 227 can be disposed on a same layer as the second drain electrode 225. For example, the second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region 102s. The second source electrode 227 can be insulated from the second gate electrode 223. The second source electrode 227 can be spaced apart from the second drain electrode 225.

The storage capacitor Cst of each pixel area PA can maintain a voltage applied to the second gate electrode 223 of the corresponding pixel area PA for one frame. For example, the storage capacitor Cst of each pixel area PA can be electrically connected between the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 223 of the corresponding pixel area PA and a second capacitor electrode electrically connected to the second source electrode 227 of the corresponding pixel area PA. The storage capacitor Cst of each pixel area PA can be formed by using a process of forming the first thin film transistor TR1 and the second thin film transistor TR2 in the corresponding pixel area PA. For example, the first capacitor electrode of each pixel area PA can be formed on a same layer as the second gate electrode 223 of the corresponding pixel area PA, and the second capacitor electrode of each pixel area PA can be formed on a same layer as the second source electrode 227 of the corresponding pixel area PA. The first capacitor electrode of each pixel area PA can include a same material as the second gate electrode 223 of the corresponding pixel area PA, and the second capacitor electrode of each pixel area PA can include a same material as the second source electrode 227 of the corresponding pixel area PA. The first capacitor electrode of each pixel area PA can be formed by a same process as the second gate electrode 223 of the corresponding pixel area PA, and the second capacitor electrode of each pixel area PA can be formed by a same process as the second source electrode 227 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA.

A plurality of insulating layers 110, 120, 130 and 140 for preventing unnecessary electrical connection can be disposed on the device substrate 100. For example, a gate insulating layer 110, an interlayer insulating layer 120, a planarization layer 130 and fences 140 can be disposed on the device substrate 100.

The gate insulating layer 110 can be disposed close to the device substrate 100. The first gate electrode and the second gate electrode 223 of each pixel area PA can be insulated from the device substrate 100 by the gate insulating layer 110. For example, an upper surface of the device substrate 100 toward the first gate electrode and the second gate electrode 223 of each pixel area PA can be covered by the gate insulating layer 110. The gate insulating layer 110 can be in direct contact with the upper surface of the device substrate 100. The first gate electrode and the second gate electrode 223 of each pixel area PA can be disposed on the gate insulating layer 110. The gate insulating layer 110 can include an insulating material. For example, the gate insulating layer 110 can include an inorganic insulating material, such as silicon oxide (SiOx) and silicon nitride (SiNx).

The interlayer insulating layer 120 can be disposed on the gate insulating layer 110. The first drain electrode and the first source electrode of each pixel area PA can be insulated from the first gate electrode of the corresponding pixel area PA by the interlayer insulating layer 120. The second drain electrode 225 and the second source region 227 of each pixel area PA can be insulated from the second gate electrode 223 of the corresponding pixel area PA by the interlayer insulating layer 120. For example, the interlayer insulating layer 120 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 120. The interlayer insulating layer 120 can include an insulating material. For example, the interlayer insulating layer 120 can include an inorganic insulating material.

The planarization layer 130 can be disposed on the interlayer insulating layer 120. The planarization layer 130 can remove a thickness difference due to the pixel driving circuit DC of each pixel area PA. For example, an upper surface of the planarization layer 130 opposite to the device substrate 100 can be a flat surface. The upper surface of the planarization layer 130 can be parallel to the upper surface of the device substrate 100. The planarization layer 130 can include an insulating material. The planarization layer 130 can include a different material from the interlayer insulating layer 120. The planarization layer 130 can include a material having a relative high fluidity. For example, the planarization layer 130 can include an organic insulating material.

The first drain electrode, the first source electrode, the second drain electrode 225 and the second source electrode 227 of each pixel area PA can be covered by the planarization layer 130. The first drain electrode of each pixel area PA can be in direct contact with the first drain region of the corresponding pixel area PA by penetrating the gate insulating layer 110 and the interlayer insulating layer 120. The first source electrode of each pixel area PA can be in direct contact with the first source region of the corresponding pixel area PA by penetrating the gate insulating layer 110 and the interlayer insulating layer 120. The second drain electrode 225 of each pixel area PA can be in direct contact with the second drain region 102d of the corresponding pixel area PA by penetrating the gate insulating layer 110 and the interlayer insulating layer 120. The second source electrode 227 of each pixel area PA can be in direct contact with the second source region 102s of the corresponding pixel area PA by penetrating the gate insulating layer 110 and the interlayer insulating layer 120.

The light-emitting device 300 of each pixel area PA can be disposed on the planarization layer 130. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the planarization layer 130 of the corresponding pixel area PA.

The first electrode 310 can include a conductive material. The first electrode 310 can include a material having a high reflectance. For example, the first electrode 310 can be a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the first electrode 310 and the second electrode 330. For example, the light-emitting unit 320 can include an emission material layer (EML). The emission material layer (EML) can include an emission material. The emission material can include an organic material, an inorganic material or a hybrid material. For example, the display apparatus according to the embodiment of the present disclosure can be an organic light-emitting display apparatus including an organic emission material.

A plurality of emission material layers (EML) can be disposed in the light-emitting unit 320. For example, the light-emitting unit 320 can include a first emission stack 321 having at least one emission material layer (EML), a second emission stack 323 having at least one emission material layer (EML), and a charge generation layer 322 disposed between the first emission stack 321 and the second emission stack 323. The charge generation layer 322 can supply holes or electrons to the first emission stack 321 and the second emission stack 323. Each of the first emission stack 321 and the second emission stack 323 can emit light.

Light generated by the second emission stack 323 can display a different color from light generated by the first emission stack 321. For example, the second emission stack 323 can include an emission material layer (EML) made of a different material from the first emission stack 321. A color represented by light generated by the light-emitting unit 320 can be a color represented by overlapping the light generated by the first emission stack 321 and the light generated by the second emission stack 323.

Each of the first emission stack 321 and the second emission stack 323 can further include at least one functional layer to smoothly supply holes or electrons. The function layer can be a hole injection layer (HIL), a hole transport layer (HTL), an electron transport layer (ETL) or an electron injection layer (EIL). Thus, in the display apparatus according to the embodiment of the present disclosure, efficiency of the light-emitting unit 320 can be improved.

The second electrode 330 can include a conductive material. The second electrode 330 can include a different material from the first electrode 310. A transmittance of the second electrode 330 can be higher than a transmittance of the first electrode 310. For example, the second electrode 330 can be a transparent electrode made of a transparent conductive material, such as ITO and IZO, or a translucent electrode in which metals such as Ag and Mg are thinly formed. Thus, in the display apparatus according to the embodiment of the present disclosure, the light generated by the light-emitting unit 320 can be emitted outside through the second electrode 330.

The fences 140 can be disposed on the planarization layer 130. The fences 140 can partially expose the first electrode 310 in each pixel area PA. For example, the fences 140 can define an emission area R-EA, G-EA and B-EA in each pixel area PA. A portion of the first electrode 310 in each pixel area PA exposed by the fences 140 can be in direct contact with the upper surface of the planarization layer 130. For example, a portion of the first electrode 310 overlapping with the emission area R-EA, G-EA and B-EA of each pixel area PA can be in direct contact with the upper surface of the planarization layer 130. The light-emitting unit 320 and the second electrode 330 of each pixel area PA can be stacked on a portion of the first electrode overlapping with the emission area R-EA, G-EA and B-EA of the corresponding pixel area PA. Thus, in the display apparatus according to the embodiment of the present disclosure, the luminance variation according to the generation location of the light emitted from the light-emitting device 300 of each pixel area PA can be prevented.

The light-emitting device 300 of each pixel area PA can be electrically connected to the second thin film transistor TR2 of the corresponding pixel area PA. For example, the first electrode 310 of each pixel area PA can be in direct contact with the second source electrode 227 of the corresponding pixel area PA by penetrating the planarization layer 130. A portion of the first electrode 310 electrically connected to the second source electrode 227 on each pixel area PA can be covered by one of the fences 140. For example, an edge of the first electrode 310 in each pixel area PA can be covered by the fences 140. Thus, in the display apparatus according to the embodiment of the present disclosure, the luminance variation according to the generation location of the light emitted from the light-emitting device 300 of each pixel area PA can be effectively prevented.

A region disposed between the emission areas R-EA, G-EA and B-EA can be defined as a non-emission area NEA. For example, the fences 140 can be disposed on the non-emission area NEA. The fences 140 can include an insulating material. For example, the fences 140 can include an inorganic insulating material. Each of the fences 140 can be a linear insulating layer with a constant thickness. The first electrode 310 of each pixel area PA can be insulated from the first electrode 310 of adjacent pixel area PA by the fences 140.

Light emitted from the light-emitting device 300 of each pixel area PA can display a same color as light emitted from the light-emitting device 300 of adjacent pixel area PA. For example, the light-emitting device 300 of each pixel area PA can emit white light. The light-emitting unit 320 of each pixel area PA can have a stacked structure same as the light-emitting unit 320 of adjacent pixel area PA. For example, the first emission stack 321 and the second emission stack 323 of each pixel area PA can have a same structure as the first emission stack 321 and the second emission stack 323 of adjacent pixel area PA. The charge generation layer 322 of each pixel area PA can include a same material as the charge generation layer 322 of adjacent pixel area PA. The first emission stack 321, the charge generation layer 322 and the second emission stack 323 of each pixel area PA can be formed by a same process as the first emission stack 321, the charge generation layer 322 and the second emission stack 323 of adjacent pixel area PA. For example, the first emission stack 321, the charge generation layer 322 and the second emission stack 323 of each pixel area PA can be formed simultaneously with the first emission stack 321, the charge generation layer 322 and the second emission stack 323 of adjacent pixel area PA.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode 330 of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. For example, the second electrode 330 of each pixel area PA can extend beyond the corresponding pixel area PA. The second electrode 330 can include a region overlapping with the non-emission area NEA. Thus, in the display apparatus according to the embodiment of the present disclosure, a process of forming the second electrode 330 in each pixel area PA can be simplified. Luminance of the light emitted from the light-emitting device 300 of each pixel area PA can be adjusted by the data signal applied to the driving circuit DC of the corresponding pixel area PA.

An encapsulation structure 400 can be disposed on the light-emitting device 300 of each pixel area PA. The encapsulation structure 400 can prevent the damage of the light-emitting device devices 300 due to the external moisture and impact. The encapsulation structure 400 can have a multi-layer structure. For example, the encapsulation structure 400 can have a stacked structure of a first encapsulating layer 410, a second encapsulating layer 420 and a third encapsulating layer 430. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting devices 300 due to the external moisture and impact can be effectively prevented. A thickness difference due to the light-emitting device 300 of each pixel area PA can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface. The upper surface of the encapsulation structure 400 can be parallel to the upper surface of the device substrate 100.

The image realized by the pixel areas PA can include various colors. For example, the emission area R-EA, G-EA and B-EA of each pixel area PA defined by the fences 140 can be one of a red emission area R-EA realizing red color, a green emission area G-EA realizing green color, and a blue emission area B-EA realizing blue color. Each of the pixel areas PA can display a different color from the pixel area PA adjacent in a first direction X. For example, in the display apparatus according to the embodiment of the present disclosure, the red emission area R-EA, the green emission area G-EA and the blue emission area B-EA can be repeatedly arranged in the first direction X. Each of the pixel area PA can display a same color as the pixel area PA adjacent in a second direction Y perpendicular to the first direction X. For example, in the display apparatus according to the embodiment of the present disclosure, the red emission areas R-EA, the green emission areas G-EA and the blue emission areas B-EA can be disposed side by side in the second direction Y.

Separating trenches ST can be disposed between the emission areas R-EA, G-EA and B-EA. For example, the separating trenches ST can be disposed on the non-emission area NEA. The separating trenches ST can include first trenches T1 extending in the second direction Y and second trenches T2 extending in the first direction X. Each of the emission areas R-EA, G-EA and B-EA can be disposed between the first trenches T1 and between the second trenches T2. The first trenches T1 and the second trenches T2 can be disposed between adjacent fences 140. For example, each of the emission areas R-EA, G-EA and B-EA can be disposed in one of regions defined by the first trenches T1 and the second trenches T2.

The first trenches T1 and the second trenches T2 can be surrounded by the planarization layer 130. Each of the first trenches T1 and each of the second trenches T2 can extend toward the device substrate 100. For example, each of the first trenches T1 and each of the second trenches T2 can be formed by removing a portion of the planarization layer 130 overlapping with the non-emission area NEA.

The first trenches T1 can be disposed between the emission areas R-EA, G-EA and B-EA adjacent in the first direction X. The charge generation layer 322 of each pixel area PA can be separated from the charge generation layers 322 of the pixel areas PA adjacent in the first direction X by the first trenches T1. The second trenches T2 can be disposed between the emission areas R-EA, G-EA and B-EA adjacent in the second direction Y. The charge generation layer 322 of each pixel area PA can be separated from the charge generation layers 322 of the pixel areas PA adjacent in the second direction Y by the second trenches T2. For example, a spaced distance between the charge generation layer 322 of each pixel area PA and the charge generation layer 322 of the pixel area PA adjacent in the first direction X can overlap one of the first trenches T1, a spaced distance between the charge generation layer 322 of each pixel area PA and the charge generation layer 322 of the pixel area adjacent in the second direction Y can overlap one of the second trenches T2. Thus, in the display apparatus according to the embodiment of the present disclosure, the driving current supplied to the light-emitting device 300 of each emission area R-EA, G-EA and B-EA can't be supplied to the emission area R-EA, G-EA and B-EA adjacent in the first direction X and/or the second direction Y through the charge generation layer 322 disposed on the corresponding emission area R-EA, G-EA and B-EA. That is, in the display apparatus according to the embodiment of the present disclosure, the generation and the emission of the light in unintended emission area R-EA, G-EA and B-EA due to the leakage current through the charge generation layer 322 can be prevented. Therefore, in the display apparatus according to the embodiment of the present disclosure, the light leakage due to the leakage current can be prevented.

The second trenches T2 can be formed by a same process as the first trenches T1. The second trenches T2 can be formed simultaneously with the first trenches T1. For example, a process of forming the first trenches T1 and the second trenches T2 can include a process of removing a portion of the planarization layer 130 on the non-emission area NEA by using a mask pattern. A width Xw of each second trench T2 can be the same as a width Yw of each first trench T1. A depth of each second trench T2 can be the same as a depth of each first trench T1. A process of forming the first emission stack 321 on each pixel area PA can be performed after the first trenches T1 and the second trenches T2 are formed. Thus, in the display apparatus according to the embodiment of the present disclosure, the first emission stack 321 of each pixel area PA can be separated from the first emission area 321 of the pixel area PA adjacent in the first direction X by one of the first trenches T1, and the first emission stack 321 of each pixel area PA can be separated from the first emission stack 321 of the pixel area PA adjacent in the second direction Y by one of the second trenches T2. For example, in the display apparatus according to the embodiment of the present disclosure, the air-gap can be formed within each first trench T1 and each second trench T2.

The second trenches T2 can be spaced apart from the first trenches T1. For example, the first trenches T1 and the second trenches T2 can't be formed between the emission areas R-EA, G-EA and B-EA adjacent in a diagonal direction inclined to the first direction X and the second direction Y. Thus, in the display apparatus according to the embodiment of the present disclosure, a portion of the planarization layer 130 disposed between the emission areas R-EA, G-EA and B-EA adjacent in the diagonal direction can't be removed by a process of forming the first trenches T1 and the second trenches T2. That is, the display apparatus according to the embodiment of the present disclosure can prevent a relatively wide groove from being formed in a portion of the planarization layer 130 disposed on the non-emission area NEA due to the intersection of the first trenches T1 and the second trenches T2. If the groove having wide width is formed in a portion of the planarization layer 130 on the non-emission area NEA, the second electrode 330 of each light-emitting device 300 extending on the non-emission area NEA can be in direct contact with the charge generation layer 322 of the corresponding light-emitting device 300 inside the relatively wide groove. Therefore, in the display apparatus according to the embodiment of the present disclosure, the electric connection of the charge generation layer 322 and the second electrode 330 on each pixel area PA due to a process of forming the first trenches T1 and the second trenches T2 can be prevented.

Separation structures 150 can be disposed between the emission areas R-EA, G-EA and B-EA adjacent in a diagonal direction. The separation structures 150 can be disposed on the non-emission area NEA. The separation structures 150 can be disposed between the first trenches T1 and the second trenches T2. For example, the separation structures 150 can be disposed side by side in the first direction X and the second direction Y. The separation structures 150 can be spaced apart from the first trenches T1 and the second trenches T2. For example, each of the separation structures 150 can be disposed on a portion of the planarization layer 140, that is not removed by a process of forming the first trenches T1 and the second trenches T2. Each of the first trenches T1 can be disposed between the separation structures 150 adjacent in the second direction Y, and each of the second trenches T2 can be disposed between the separation structure 150 adjacent in the first direction X.

Each of the separation structures 150 can have an under-cut structure. Thus, in the display apparatus according to the embodiment of the present disclosure, the charge generation layer 322 of each pixel area PA can be separated from the charge generation layer 322 of the pixel area PA adjacent in a diagonal direction by one of the separation structures 150. For example, a spaced distance between the charge generation layer 322 of each pixel area PA and the charge generation layer 322 of the pixel area PA adjacent in a diagonal direction can overlap one of the separation structures 150. Therefore, in the display apparatus according to the embodiment of the present disclosure, the driving current supplied to the light-emitting device 300 of each emission area R-EA, G-EA and B-EA can't be supplied to the emission area R-EA, G-EA and B-EA adjacent in a diagonal direction through the charge generation layer on the corresponding emission area R-EA, G-EA and B-EA. That is, in the display apparatus according to the embodiment of the present disclosure, the leakage of the driving current supplied to the light-emitting device 300 of each emission area R-EA, G-EA and B-EA can be prevented by the first trenches T1, the second trenches T2 and the separation structures 150.

Each of the separation structures 150 can have a stacked structure of a separating support 151 and a separating cap 152. The under-cut structure of each separation structure 150 can be formed by the separating support 151 and the separating cap 152 of the corresponding separation structure 150. For example, a lower surfaced of the separating cap 152 toward the device substrate 100 can be greater than a width of the separating support 151. The separating support 151 and the separating cap 152 can include an insulating material. For example, the separating support 151 and the separating cap 152 can include an inorganic insulating material. Thus, the display apparatus according to the embodiment of the present disclosure can prevent each light-emitting device 300 from being electrically connected to adjacent light-emitting device 300 by the separation structures 150. The separating cap 152 can include a different material from the separating support 151.

A length 150x of the separating cap 152 in the first direction X can be greater than the width Xw of each first trench T1. A length 150y of the separating cap 152 in the second direction Y can be greater than the width Yw of each second trench T2. Thus, in the display apparatus according to the embodiment of the present disclosure, the charge generation layer 322 of each emission area R-EA, G-EA and B-EA can be effectively separated from the charge generation layers 322 of adjacent emission areas R-EA, G-EA and B-EA by the first trenches T1, the second trenches T2 and the separation structures 150.

The separating support 151 of each separation structure 150 can be disposed between adjacent fences 140. The separating support 151 of each separation structure 150 can have a greater thickness than each fence 140. For example, a distance between the device substrate 100 and the separating cap 152 of each separation structure 150 can be larger than a distance between the device substrate 100 and the charge generation layer 322 of each emission area R-EA, G-EA and B-EA. The separating support 151 and the separating cap 152 of each separation structure 150 can include a different material from the fences 140. Thus, in the display apparatus according to the embodiment of the present disclosure, the charge generation layer 322 of each emission area R-EA, G-EA and B-EA can be effectively separated from the charge generation layer 322 of the emission area R-EA, G-EA and B-EA adjacent in a diagonal direction by the separation structures 150. The second emission stack 323 and the second electrode 330 of each emission area R-EA, G-EA and B-EA can extend onto adjacent separation structures 150. For example, the separating support 151 and the separating cap 152 of each separation structure 150 can be surrounded by the second emission stack 323 of adjacent emission area R-EA, G-EA and B-EA. That is, in the display apparatus according to the embodiment of the present disclosure, an end of the charge generation layer 322 of each emission area R-EA, G-EA and B-EA that is separated by the separation structures 150 can be covered by the second emission stack 323 of the corresponding emission area R-EA, G-EA and B-EA. Therefore, in the display apparatus according to the embodiment of the present disclosure, the leakage current through the charge generation layer 322 of each emission area R-EA, G-EA and B-EA can be effectively prevented.

Color filters 500R, 500G and 500B can be disposed on the emission areas R-EA, G-EA and B-EA of each pixel area PA. For example, the color filters 500R, 500G and 500B can include red color filters 500R disposed on the red emission areas R-EA, green color filters 500G disposed on the green emission areas G-EA and blue color filters 500B disposed on the blue emission areas B-EA. The light emitted from the light-emitting device 300 of each pixel area PA can display a specific color passing through the color filter 500R, 500G and 500B of the corresponding pixel area PA. The color filter 500R, 500G and 500B of each pixel area PA can be disposed on a path of the light emitted from the light-emitting device 300 of the corresponding pixel area PA. For example, the color filter 500R, 500G and 500B of each pixel area PA can be disposed on the encapsulation structure 400 of the corresponding pixel area PA. The color filter 500R, 500G and 500B of each pixel area PA can have a greater size than the emission area R-EA, G-EA and B-EA of the corresponding pixel area PA. For example, a boundary of adjacent color filters 500R, 500G and 500B can be disposed on the non-emission area NEA. The separating trenches ST and the separation structures 150 can overlap the boundary of adjacent color filters 500R, 500G and 500B. Thus, in the display apparatus according to the embodiment of the present disclosure, the decrease in the quality of the image due to the light that does not pass through the color filters 500R, 500G and 500B can be prevented.

A filter passivation layer 700 can be disposed on the color filter 500R, 500G and 500B of each pixel area PA. The filter passivation layer 700 can prevent the damage of the color filters 500R, 500G and 500B due to the external impact and moisture. The filter passivation layer 700 can include an insulating material. For example, the filter passivation layer 700 can include at least one of an inorganic insulating material and an organic insulating material. The filter passivation layer 700 can have a multi-layer structure. For example, the filter passivation layer 700 can have a structure in which an inorganic passivation layer made of an inorganic insulating material is formed on an organic passivation layer made of an organic insulating material. Thus, in the display apparatus according to the embodiment of the present disclosure, the damage of the color filter 500R, 500G and 500B in each pixel area PA due to the external impact and moisture can be effectively prevented.

Accordingly, the display apparatus according to the embodiment of the present disclosure can include the first trenches T1 disposed between the emission areas R-EA, G-EA and B-EA adjacent in the first direction X, the second trenches T2 disposed between the emission areas R-EA, G-EA and B-EA adjacent in the second direction Y, and the separation structures 150 disposed between the emission areas R-EA, G-EA and B-EA adjacent in a diagonal direction inclined to the first direction X and the second direction Y, wherein the first trenches T1 and the second trenches T2 can be formed in the planarization layer 130 of the non-emission area NEA, wherein the separation structures 150 spaced apart from the first trenches T1 and the second trenches T2 can be formed on the planarization layer 130 of the non-emission area NEA, and wherein each of the separation structures 150 can have an under-cut structure. Thus, in the display apparatus according to the embodiment of the present disclosure, the leakage of the driving current supplied to the light-emitting device 300 of each emission area R-EA, G-EA and B-EA can be prevented by the first trenches T1, the second trenches T2 and the separation structures 150. That is, in the display apparatus according to the embodiment of the present disclosure, the generation and the emission of the light in unintended region due to the leakage current through the charge generation layer 322 of each emission area R-EA, G-EA and B-EA can be prevented. Therefore, in the display apparatus according to the embodiment of the present disclosure, the emission efficiency of the light-emitting device 300 on each emission area R-EA, G-EA and B-EA can be improved. And, in the display apparatus according to the embodiment of the present disclosure, the luminance of the light emitted from each emission area R-EA, G-EA and B-EA can be improved.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third well region, a third drain region, a third source region, a third gate electrode, a third drain electrode and a third source electrode. The third well region, the third drain region and the third source region can be formed within the device substrate 100. The third gate electrode of each pixel area PA can be electrically connected to the corresponding gate line GL, the third drain electrode of each pixel area PA can be electrically connected to an initial line applying an initial signal, and the third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 of each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the first well, the second drain region 102d and the second source region 102s of each pixel area PA can include P-type impurities, and the first drain region, the first source region and the second well region 102w of each pixel area PA can include N-type impurities. However, in the display apparatus according to another embodiment of the present disclosure, the second well region 102w of each pixel area PA can include conductive impurities same as the first well region of the corresponding pixel area PA. For example, in the display apparatus according to another embodiment of the present disclosure, the first well region and the second well region 102w of each pixel area PA can include P-type impurities. The first drain region, the first source region, the second drain region 102d and the second source region 102s of each pixel area PA can include N-type impurities. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the device substrate 100 can be a wafer formed of a semiconductor material, such as silicon. However, in the display apparatus according to another embodiment of the present disclosure, the device substrate 100 can include glass or plastic. In the display apparatus according to another embodiment of the present disclosure, the driving circuit DC of each pixel area PA can be formed on the upper surface of the device substrate 100. For example, in the display apparatus according to another embodiment of the present disclosure, a buffer layer including an inorganic insulating material, such as silicon oxide (SiOx) and silicon nitride (SiNx), can be formed on the upper surface of the device substrate 100, the first thin film transistor TR1 of each pixel area PA can include a first semiconductor pattern formed on the buffer layer, and the second thin film transistor TR2 of each pixel area PA can include a second semiconductor pattern formed on the buffer layer. The first semiconductor pattern and the second semiconductor pattern can include a semiconductor material. For example, the first semiconductor pattern and the second semiconductor pattern can include an oxide semiconductor, such as IGZO. The second semiconductor pattern can include a same material as the first semiconductor pattern. Thus, in the display apparatus according to another embodiment of the present disclosure, the degree of freedom for the material of the device substrate 100 and the configuration of each driving circuit DC can be improved.

The display apparatus according to the embodiment of the present disclosure is described that the first electrode 310 of each pixel area PA can have a relative higher reflectance. However, in the display apparatus according to another embodiment of the present disclosure, the first electrode 310 of each pixel area PA can be a transparent electrode having a high transmittance, and a reflective electrode can be disposed between the device substrate 100 and the first electrode 310 of each pixel area PA. For example, the first electrode 310 of each pixel area PA can be made of a transparent conductive material, such as ITO and IZO. A distance between the reflective electrode and the first electrode 310 in each pixel area PA can be determined by a color realized in the emission area R-EA, G-EA and B-EA of the corresponding pixel area PA. For example, a distance between the reflective electrode and the first electrode 310 in the red emission area R-EA can be different from a distance between the reflective electrode and the first electrode 310 in the green emission area G-EA and a distance between the reflective electrode and the first electrode 310 in the blue emission area B-EA. That is, in the display apparatus according to another embodiment of the present disclosure, the light having a wavelength range corresponding to a color realized by each emission area R-EA, G-EA and B-EA can resonate between the reflective electrode and the second electrode 330 of the corresponding emission area R-EA, G-EA and B-EA. Therefore, in the display apparatus according to another embodiment of the present disclosure, the concentration efficiency and the color reproduction of each emission area R-EA, G-EA and B-EA can be improved.

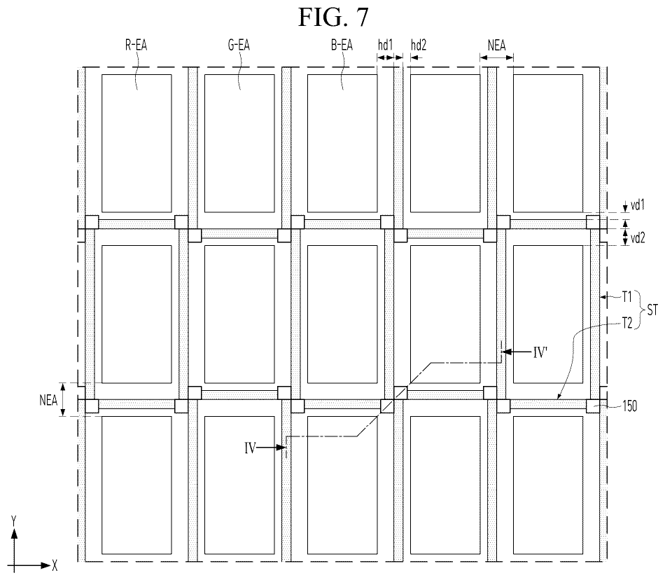

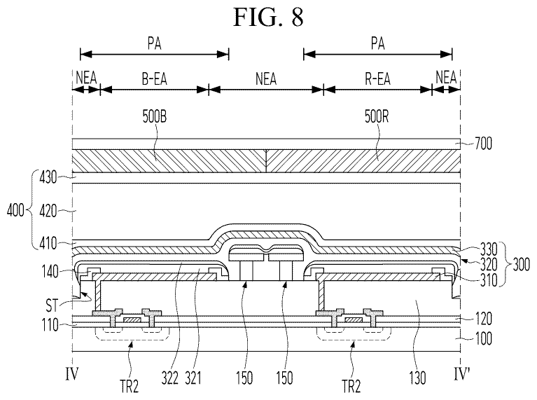

The display apparatus according to the embodiment of the present disclosure is described that the first trenches T1 can be disposed side by side in the second direction Y, and the second trenches T2 can be disposed side by side in the first direction X. However, in the display apparatus according to another embodiment of the present disclosure, the first trenches T1 and the second trenches T2 can be arranged in various shapes. For example, in the display apparatus according to the embodiment of the present disclosure, two first trenches T1 adjacent in the second direction Y can be arranged alternately in the first direction X, two second trenches T2 adjacent in the first direction X can be arrange alternately in the second direction Y, and two separation structures 150 can be disposed between two emission areas R-EA, G-EA and B-EA adjacent in a diagonal direction, as shown in FIGS. 7 and 8.

Each of the first trenches T1 disposed between two emission areas R-EA, G-EA and B-EA adjacent in the first direction X can have a different distance from the two corresponding emission areas R-EA, G-EA and B-EA. For example, a distance hd1 between each of the first trenches T1 and the emission area R-EA, G-EA and B-EA disposed on a side of the corresponding first trench T1 can be different from a distance hd2 between the corresponding first trench T1 and the emission area R-EA, G-EA and B-EA disposed the other side of the corresponding first trench T1. Each of the second trenches T2 disposed between two emission areas R-EA, G-EA and B-EA adjacent in the second direction Y can have a different distance from the two corresponding emission areas R-EA, G-EA and B-EA. For example, a distance vd1 between each of the second trenches T2 and the emission area R-EA, G-EA and B-EA disposed on a side of the corresponding second trench T2 can be different from a distance vd2 between the corresponding second trench T2 and the emission area R-EA, G-EA and B-EA disposed the other side of the corresponding second trench T2. Each of the emission areas R-EA, G-EA and B-EA can include a second side opposite to a first side, a third side perpendicular to the first side, and a fourth side opposite to the third side, a distance hd1 between each of the emission area R-EA, G-EA and B-EA and the first trench T1 disposed on the first side of the corresponding emission area R-EA, G-EA and B-EA can be the same as a distance between the corresponding emission area R-EA, G-EA and B-EA and the first trench T1 disposed on the second side of the corresponding emission area R-EA, G-EA and B-EA, a distance vd1 between each emission area R-EA, G-EA and B-EA and the second trench T2 disposed on the third side of the corresponding emission area R-EA, G-EA and B-EA can be the same as a distance between the corresponding emission area R-EA, G-EA and B-EA and the second trench T2 disposed on the fourth side of the corresponding emission area R-EA, G-EA and B-EA. For example, a distance hd1 between each emission area R-EA, G-EA and B-EA and the first trench T1 disposed on the first side of the corresponding emission area R-EA, G-EA and B-EA can be the same as a distance vd2 between the second trench T2 disposed on the third side of the corresponding emission area R-EA, G-EA and B-EA and the emission area R-EA, G-EA and B-EA adjacent to the corresponding emission area R-EA, G-EA and B-EA in the second direction Y. Thus, in the display apparatus according to the embodiment of the present disclosure, the intersection of the first trenches T1 and the second trenches T2 due to a process error can be prevented, and the leakage of the driving current supplied to the light-emitting device 300 of each emission area R-EA, G-EA and B-EA can be prevented.

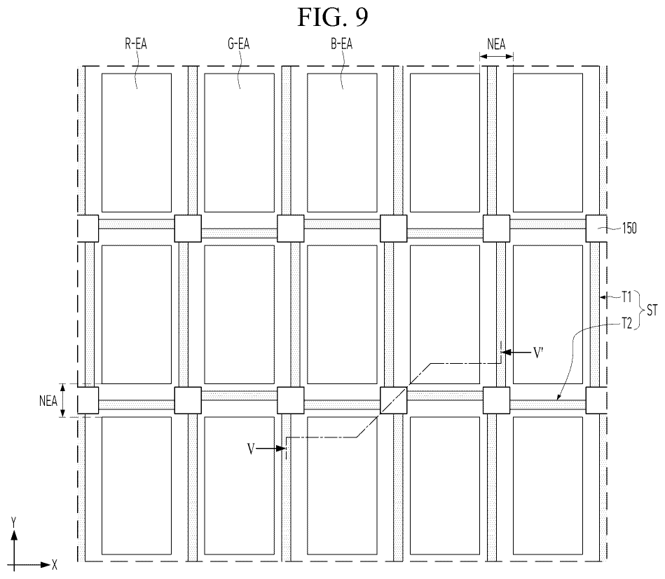

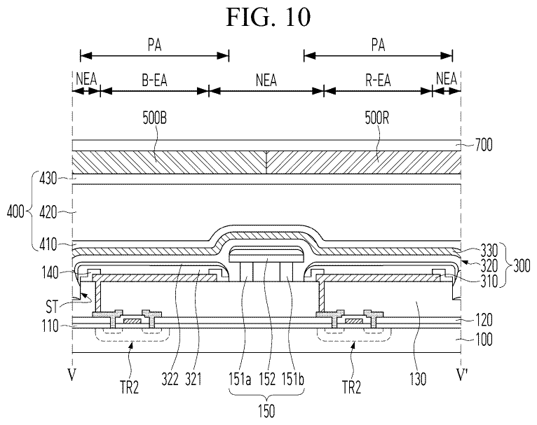

In the display apparatus according to another embodiment of the present disclosure, each of the separation structures 150 can include a plurality of separating supports 151 supporting a single separating cap 152. For example, in the display apparatus according to the embodiment of the present disclosure, two first trenches T1 adjacent in the second direction Y can be arranged alternately, two second trenches T2 adjacent in the first direction X can be arranged alternately, a single separation structure can be disposed between two emission areas R-EA, G-EA and B-EA adjacent in a diagonal direction, and each of the separation structures can include a first separating support 151a, a second separating support 151b and a separating cap 152, as shown in FIGS. 9 and 10. The second separating support 151b can be disposed side by side with the first separating support 151a on the planarization layer 130. For example, the second separating support 151b can be disposed side by side with the first separating support 151a in a diagonal direction inclined to the first direction X and the second direction Y. The first separating support 151a can be disposed side by side in the second direction Y with one of the first trenches T1 that are alternately arranged, and the first separating support 151a can be disposed side by side in the first direction X with one of the second trenches T2 that are alternately arranged. The second separating support 151b can be disposed side by side in the second direction Y with the first trench T1 spaced apart from the first separating support 151a in the first direction X, and the second separating support 151b can be disposed side by side in the first direction X with the second trench T2 spaced apart from the first separating support 151a in the second direction Y. The separating cap 152 can be disposed on the first separating support 151a and the second separating support 151b. Thus, in the display apparatus according to the embodiment of the present disclosure, each of the separation structures 150 can be formed in various shapes, regardless of arrangement of the first trenches T1 and the second trenches T2. Therefore, in the display apparatus according to the embodiment of the present disclosure, the degree of freedom for the arrangement of the first trenches T1 and the second trenches T2 and the shape of the separation structures 150 can be improved.

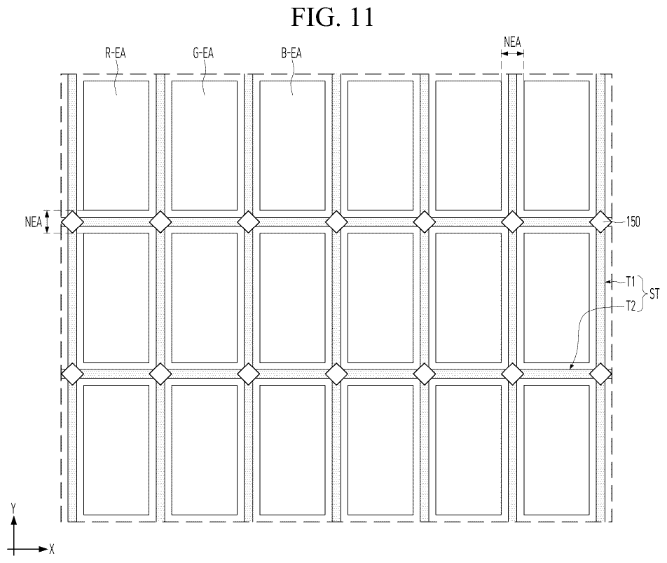

The display apparatus according to the embodiment of the present disclosure is described that a plane of each separating cap 152 can have a square shape. However, in the display apparatus according to another embodiment of the present disclosure, a plane of each separating cap 152 can have various shapes. For example, in the display apparatus according to another embodiment of the present disclosure, the separating cap of each separation structure 150 can have a diamond-shaped plane including a side surface extending in a diagonal direction inclined to the first direction X and the second direction Y, as shown in FIG. 11. The maximum width of each separating cap in the first direction X can be greater than a width of each first trench T1. The maximum width of each separating cap in the second direction Y can be greater than a width of each second trench T2. Thus, in the display apparatus according to another embodiment of the present disclosure, the charge generation layers of the emission areas R-EA, G-EA and B-EA adjacent in a diagonal direction can be effectively separated by each separation structure 150.

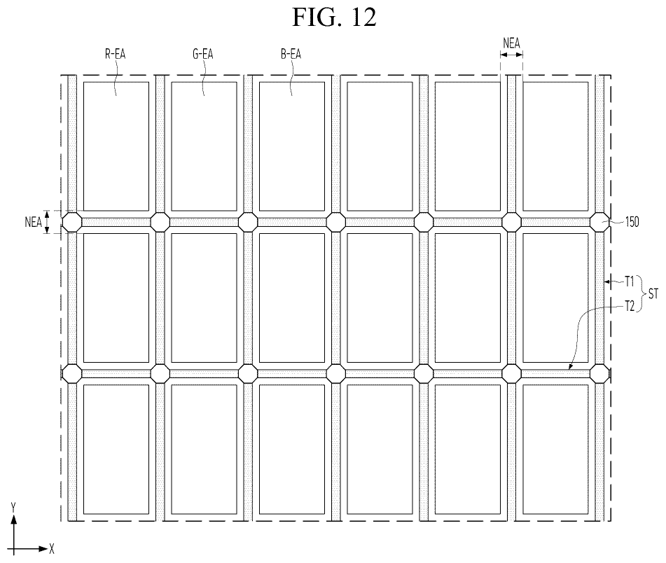

In the display apparatus according to another embodiment of the present disclosure, the separation cap of each separation structure 150 can have a hexagonal-shaped plane, as shown in FIG. 12. The maximum width of each separating cap in the first direction X can be greater than a width of each first trench T1. The maximum width of each separating cap in the second direction Y can be greater than a width of each second trench T2. Thus, in the display apparatus according to another embodiment of the present disclosure, the degree of freedom for the shape of the separating cap of each separation structure.

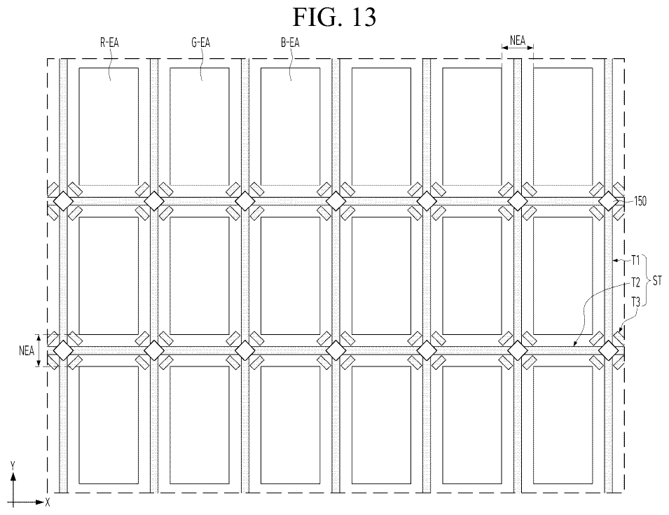

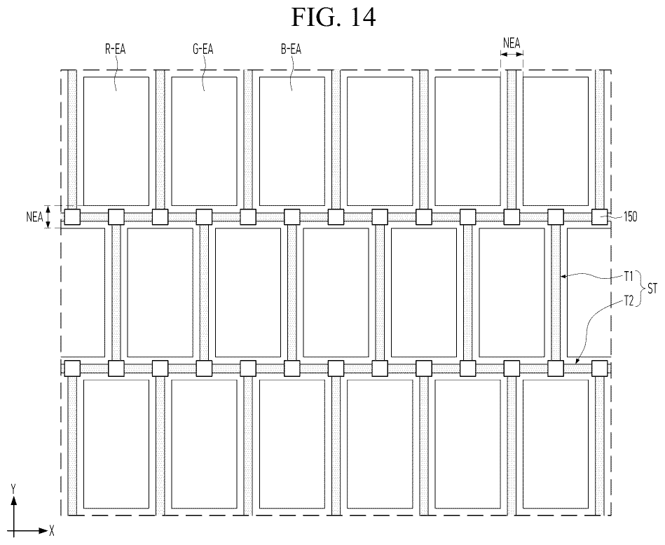

The display apparatus according to the embodiment of the present disclosure is described that the separating trenches ST can include the first trenches T1 extending in the second direction Y and the second trenches T2 extending in the first direction X. However, in the display apparatus according to another embodiment of the present disclosure, the separating trenches ST can include the trenches T1 and T2 having various shapes. For example, in the display apparatus according to another embodiment of the present disclosure, the separating trenches ST can include first trenches T1 extending in the second direction Y between the separation structures 150, second trenches T2 extending in the first direction X between the separation structures 150, and third trenches T3 disposed between the emission areas R-EA, G-EA and B-EA and the separation structures 150, as shown in FIG. 13. Each of the third trenches T3 can extend in a diagonal direction inclined to the first direction X and the second direction Y. Each of the third trenches T2 can extend in a direction crossing between one of the emission areas R-EA, G-EA and B-EA and one of the separation structures 150. For example, the separating cap of each separation structure 150 can have a diamond-shaped plane, and the third trenches T3 can be disposed on each side of the separating cap. Thus, in the display apparatus according to another embodiment of the present disclosure, two third trenches T3 can be disposed between the emission areas R-EA, G-EA and B-EA adjacent in a diagonal direction, and a single separation structure 150 can be disposed between adjacent two third trenches T3. Each of the third trenches T3 can be disposed close to one of the first trenches T1 and one of the second trenches T2.

The third trenches T3 can be formed by a same process as the first trenches T1 and the second trenches T2. For example, the third trenches T3 can be formed simultaneously with the first trenches T1 and the second trenches T2. A width of each third trench T3 can be the same as a width of each first trench T1 and a width of each second trench T2. Each of the third trenches T3 can't intersect the first trenches T1 and the second trenches T2. That is, in the display apparatus according to another embodiment of the present disclosure, the charge generation layer of each emission area R-EA, G-EA and B-EA can be separated from the charge generation layer of the emission area R-EA, G-EA and B-EA adjacent in a diagonal direction by two third trenches T3 and a single separation structure 150. Therefore, in the display apparatus according to the embodiment of the present disclosure, the leakage current due to the charge generation layer of each emission area R-EA, G-EA and B-EA can be effectively prevented.

The display apparatus according to the embodiment of the present disclosure is described that the emission areas R-EA, G-EA and B-EA can be disposed side by side in the first direction X and the second direction Y. However, in the display apparatus according to another embodiment of the present disclosure, the emission areas R-EA, G-EA and B-EA can be arranged alternately in the first direction X or the second direction Y. For example, in the display apparatus according to another embodiment of the present disclosure, the emission areas R-EA, G-EA and B-EA can be disposed side by side in the first direction X, and the emission areas R-EA, G-EA and B-EA can be disposed alternately in the second direction Y, as shown in FIG. 14. Each of the first trenches T1 can be disposed between the emission areas R-EA, G-EA and B-EA adjacent in the second direction Y. Thus, in the display apparatus according to another embodiment of the present disclosure, even when the first trenches and the second trenches partially intersect due to a process error, the electrical connection between the charge generation layer and the second electrode on each emission area R-EA, G-EA and B-EA can be minimized. Therefore, in the display apparatus according to another embodiment of the present disclosure, the light leakage due to the leakage current can be effectively prevented. And, in the display apparatus according to the embodiment of the present disclosure, the luminance of the light emitted from each emission area R-EA, G-EA and B-EA can be effectively improved.

In the result, the display apparatus according to the embodiments of the present disclosure can comprise the separation structures disposed side by side in the first direction and the second direction perpendicular to the first direction, the separating trenches disposed between the separation structures, and the light-emitting devices disposed on the emission areas defined by the separating trenches, wherein each of the light-emitting device can include the charge generation layer disposed between the first emission stack and the second emission stack, wherein the separating trenches can include the first trenches extending in the second direction and the second trenches extending in the first direction, and wherein each of the separation structures spaced apart from the first trenches and the second trenches can have an under-cut structure. Thus, in the display apparatus according to the embodiments of the present disclosure, the charge generation layers of the emission areas adjacent in the first direction can be separated by the first trenches, the charge generation layers of the emission areas adjacent in the second direction can be separated by the second trenches, and the charge generation layers of the emission areas adjacent in a diagonal direction inclined to the first direction and the second direction can be separated by the separation structures. That is, in the display apparatus according to the embodiments of the present disclosure, the leakage current through the charge generation layer of each emission area can be prevented by the first trenches, the second trenches and the separation structures. And, in the display apparatus according to the embodiments of the present disclosure, the second electrode of each light-emitting device can't be electrically connected to the charge generation layer of the corresponding light-emitting device between the emission areas adjacent in a diagonal direction. Thereby, in the display apparatus according to the embodiments of the present disclosure, the efficiency of the light-emitting device on each emission area can be improved. Further, in the display apparatus according to the embodiments of the present disclosure, the production energy can be reduced by process optimization.

What is claimed is:

1. A display apparatus, comprising:
separation structures disposed on a device substrate, the separation structures disposed side by side in a first direction and a second direction perpendicular to the first direction;
first trenches disposed between the separation structures adjacent in the second direction, the first trenches extending in the second direction;
second trenches disposed between the separation structures adjacent in the first direction, the second tranches extending in the first direction; and
light-emitting devices disposed on emission areas defined by the first trenches and the second trenches,
each of the light-emitting devices includes a charge generation layer disposed between a first emission stack and a second emission stack,
each of the separation structures includes a separating support and a separating cap disposed on the separating support, and
wherein a lower surface of the separating cap toward the device substrate has a greater that a width of the separating support.

2. The display apparatus according to the claim 1, wherein the separating support and the separating cap include an insulating material.

3. The display apparatus according to claim 1, wherein a distance between the device substrate and the lower surface of the separating cap is larger than a distance between the device substrate and the charge generation layer.

4. The display apparatus according to claim 1, wherein a width of each second trench is the same as a width of each first trench.

5. The display apparatus according to claim 1, further comprising fences partially exposing a first electrode of each light-emitting structure,
wherein the separating support of each separation structure is disposed between the fences.

6. The display apparatus according to claim 5, wherein the separating support of each separation structure includes a different material from the fences.

7. A display apparatus, comprising:
a first light-emitting device disposed on a first emission area, the first light-emitting device including a first charge generation layer;
a second light-emitting device disposed on a second emission area adjacent to the first emission area in a first direction, the second light-emitting device including a second charge generation layer;
a first trench disposed between the first emission area and the second emission area, the first trench extending a second direction perpendicular to the first direction;
a third light-emitting device disposed on a third emission area adjacent to the first emission area in the second direction, the third light-emitting device including a third charge generation layer;
a second trench disposed between the first emission area and the second emission area, the second trench extending in the first direction; and
a separation structure disposed between the second emission area and the third emission area, the separation structure having an under-cut structure,
wherein the first charge generation layer, the second charge generation layer and the third charge generation layer are spaced apart from each other, and
wherein the first trench and the second trench are spaced apart from the separation structure.

8. The display apparatus according to claim 7, wherein a spaced area between the first charge generation layer and the second charge generation layer overlaps the first trench,
wherein a spaced area between the first charge generation layer and the third charge generation layer overlaps the second trench, and
wherein a spaced area between the second charge generation layer and the third charge generation layer overlaps the separation structure.

9. The display apparatus according to claim 7, wherein the separation structure includes a separating support and a separating cap disposed on the separating support,
wherein the maximum width of the separating cap in the first direction is larger than a width of the first trench, and
wherein the maximum width of the separating cap in the second direction is larger than a width of the second trench.

10. The display apparatus according to claim 9, wherein the maximum width of the separating cap in the first direction is smaller than a distance between the first emission area and the second emission area, and
wherein the maximum width of the separating cap in the second direction is smaller than a distance between the first emission area and the third emission area.

11. The display apparatus according to claim 7, wherein a distance between the first emission area and the first trench is different from a distance between the first trench and the second emission area, and
wherein a distance between the first emission area and the second trench is different from a distance between the second trench and the third emission area.

12. The display apparatus according to claim 11, wherein the distance between the first emission area and the first trench is the same as the distance between the second trench and the third emission area, and
wherein the distance between the first emission area and the second trench is the same as the distance between the first emission area and the second trench.

13. The display apparatus according to claim 11, wherein the separation structure includes a first support disposed side by side with the first trench in the second direction, a second support disposed side by side with the second trench in the first direction, and a separating cap disposed on the first support and the second support.

14. The display apparatus according to claim 7, further comprising a third trench disposed between the first emission area and the separation structure, the third trench extending in a direction inclined to the first direction and the second direction,
wherein the third trench is spaced apart from the first trench and the second trench.

15. The display apparatus according to claim 14, wherein a width of the third trench is the same as a width of the first trench and a width of the second trench.
